(19) United States
(12) Patent Application Publication
(10) Pub. No.: US 2026/0299437 A1
(43) Pub. Date: Oct. 1, 2026

(54) SYSTEM AND METHOD FOR TAILORING CHUCK STIFFNESS

(71) Applicant: ASML Netherlands B.V., Veldhoven (NL)

(72) Inventors: Venkata Siva Chaithanya CHILLARA, Norwalk, CT (US); Muthukumaran LOGANATHAN, Norwalk, CT (US); Matthew Anthony SORNA, Washington, DC (US)

(73) Assignee: ASML Netherlands B.V., Veldhoven (NL)

(21) Appl. No.: 19/163,286

(22) PCT Filed: Mar. 1, 2024
(86) PCT No.: PCT/EP2024/055482

§ 371 Date: Sep. 8, 2025

Related U.S. Application Data
(60) Provisional application No. 63/492,369, filed on Mar. 27, 2023.

(51) Int. Cl. G03F 7/00

(52) U.S. Cl. CPC G03F 7/707; G03F 7/70725; G03F 7/70758; G03F 7/70783

(57) ABSTRACT

A lithographic apparatus that includes an illumination system, a patterning system, a projection system, and a reticle stage. The illumination system produces a beam of radiation. The patterning system imparts a pattern on the beam. The patterning system includes a reticle. The projection system projects the patterned beam on a substrate. The reticle stage includes a reticle clamp for supporting the reticle and a chuck for supporting the reticle clamp. The chuck includes a patterned internal structure. A portion of the patterned internal structure is an auxetic structure. The auxetic structure is thicker or thinner than other portions of the patterned internal structure.

### CROSS-REFERENCE TO RELATED APPLICATION

This application claims priority of U.S. application 63/492,369 which was filed on 27 Mar. 2023, and which is incorporated herein in its entirety by reference.

### FIELD

The present disclosure relates to mitigating material deformations, for example, tailoring the stiffness of a reticle stage chuck in lithography apparatuses and systems.

### BACKGROUND

A lithographic apparatus is a machine constructed to apply a desired pattern onto a substrate. A lithographic apparatus can be used, for example, in the manufacture of integrated circuits (ICs). A lithographic apparatus can, for example, project a pattern of a patterning device (e.g., a mask, a reticle) onto a layer of radiation-sensitive material (photoresist or simply “resist”) provided on a substrate.

To project a pattern on a substrate a lithographic apparatus can use electromagnetic radiation. The wavelength of this radiation determines the minimum size of features which can be formed on the substrate. A lithographic apparatus, which uses deep ultraviolet (DUV) radiation with wavelengths of 193 nm or 248 nm, can be used to form features on a substrate. A DUV lithographic apparatus can also use immersion lens configurations, wherein water between the lens and the wafer helps to increase resolution. In addition, a lithographic apparatus, which uses extreme ultraviolet (EUV) radiation, having a wavelength within the range 4-20 nm, for example 6.7 nm or 13.5 nm, can be used to form smaller features on a substrate than a lithographic apparatus which uses, for example, radiation with a wavelength of 193 nm.

In lithographic processes, a reticle stage chuck clamps a reticle during exposure of a pattern onto a wafer. To enable high throughput lithography, actuators power the reticle stage to scan at high velocity and acceleration. These actuators push or pull on the chuck, which can cause deformations of the chuck and its interfaces, such as reticle clamps and encoder scales.

### SUMMARY

Accordingly, it is desirable to reduce deformations of the chuck, reticle clamps, and encoder scales in a reliable, uniform, and efficient manner. For example, a reticle stage can include a patterned internal structure to increase stiffness of the chuck, thereby counteracting deformations.

In some aspects, a lithographic apparatus comprises an illumination system, a patterning system, a projection system, and a reticle stage. The illumination system is configured to produce a beam of radiation. The patterning system is configured to impart a pattern on the beam. The patterning system comprises a reticle. The projection system is configured to project the patterned beam on a substrate. The reticle stage comprises a reticle clamp configured to support the reticle and a chuck configured to support the reticle clamp. The chuck includes a patterned internal structure. A portion of the patterned internal structure is an auxetic structure. The auxetic structure is thicker or thinner than other portions of the patterned internal structure.

In some aspects, a system comprises a reticle clamp configured to support a reticle and a chuck configured to support the reticle clamp. The chuck includes a patterned internal structure. A portion of the patterned internal structure is an auxetic structure. The auxetic structure is thicker or thinner than other portions of the patterned internal structure.

In some aspects, a method comprises pushing or pulling a chuck in a first direction during a first time period with first and second actuators; pushing or pulling the chuck in a second direction, opposite the first direction, during a second time period with third and fourth actuators; and counteracting deformation of the chuck from the pushing or pulling with an auxetic structure within or coupled to the chuck, the auxetic structure being configured to expand in a transverse direction to the first and second directions.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIGS. 2 and 3 show a reticle stage, according to some aspects.

FIGS. 4 and 5 show a reticle exchange apparatus, according to some aspects.

FIGS. 6A, 6B, and 6C show a reticle exchange apparatus in different configurations, according to some aspects.

FIG. 7 shows a cross-section of a reticle stage chuck in a horizontal XY-plane, according to some aspects.

FIG. 8 shows a cross-section of a reticle stage chuck in a vertical YZ-plane, according to some aspects.

FIG. 9 shows a perspective view of a chuck with an auxetic structure, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., ±10%, ±20%, or ±30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic System

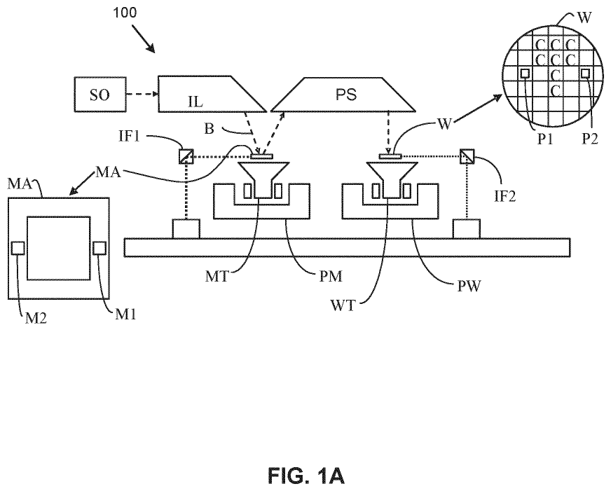

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber V. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In some aspects, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

In some aspects, lithographic apparatus 100′ includes a deep ultraviolet (DUV) source, which is configured to generate a beam of DUV radiation for DUV lithography. In general, the DUV source is configured in a radiation system, and a corresponding illumination system is configured to condition the DUV radiation beam of the DUV source.

### Example Reticle Stage

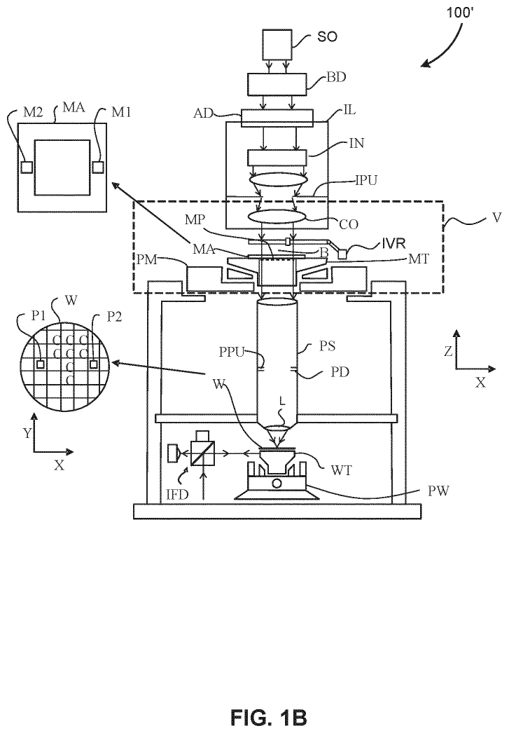

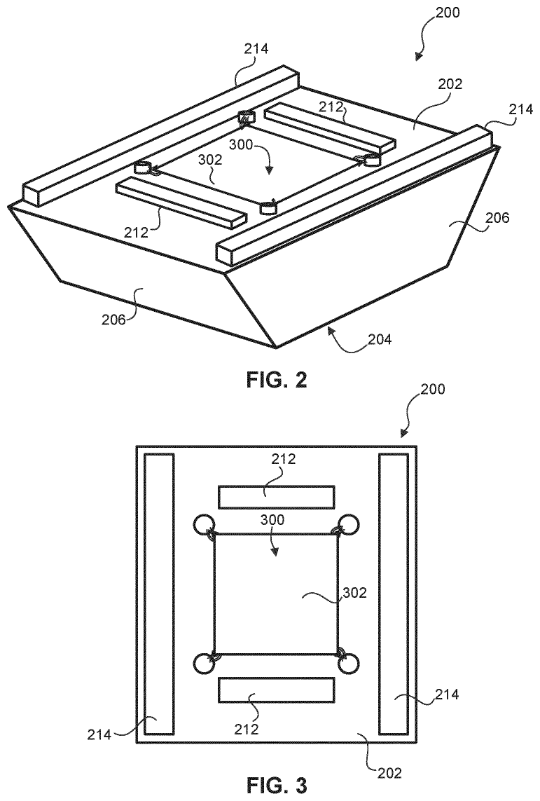

FIGS. 2 and 3 show a reticle stage 200, according to some aspects. Reticle stage 200 can include top stage surface 202, bottom stage surface 204, side stage surfaces 206, and clamp 300. In some aspects, reticle stage 200 with clamp 300 can be implemented in lithographic apparatus 100 and/or lithographic apparatus 100′. For example, reticle stage 200 can be support structure MT in lithographic apparatus 100 and/or lithographic apparatus 100′. In some aspects, clamp 300 can be disposed on top stage surface 202. For example, as shown in FIG. 2, clamp 300 can be disposed at a center of top stage surface 202 with clamp frontside 302 facing perpendicularly away from top stage surface 202.

In some lithographic apparatuses, for example, lithographic apparatus 100 and/or lithographic apparatus 100′, a reticle stage 200 with a clamp 300 can be used to hold and position a reticle 408 for scanning or patterning operations. In one example, the reticle stage 200 can rely on powerful drives, large balance masses, and heavy frames to support it. In one example, the reticle stage 200 can have a large inertia and can weigh over 500 kg to propel and position a reticle 408 weighing about 0.5 kg. To accomplish reciprocating motions of the reticle 408, which are typically found in lithographic scanning or patterning operations, accelerating and decelerating forces can be provided by linear motors that drive the reticle stage 200.

In some aspects, as shown in FIGS. 2 and 3, reticle stage 200 can include first encoder 212 and second encoder 214 for positioning operations. For example, first and second encoders 212 and 214 can be interferometers. First encoder 212 can be attached along a first direction, for example, a transverse direction (i.e., X-direction) of reticle stage 200. And second encoder 214 can be attached along a second direction, for example, a longitudinal direction (i.e., Y-direction) of reticle stage 200. In some aspects, as shown in FIGS. 2 and 3, first encoder 212 can be orthogonal to second encoder 214.

As shown in FIGS. 2 and 3, reticle stage 200 can include clamp 300. Clamp 300 is configured to hold reticle 408 in a fixed plane on reticle stage 200. Clamp 300 includes clamp frontside 302 and can be disposed on top stage surface 202. In some aspects, clamp 300 can use mechanical, vacuum, electrostatic, or other suitable clamping techniques to hold and secure an object. In some aspects, clamp 300 can be an electrostatic clamp, which can be configured to electrostatically clamp (i.e., hold) an object, for example, reticle 408 in a vacuum environment. For EUV generation performed in a vacuum environment, it can be difficult to use vacuum clamps to clamp a mask or reticle. Instead, electrostatic clamp(s) can be used. For example, clamp 300 can include an electrode, a resistive layer on the electrode, a dielectric layer on the resistive layer, and burls projecting from the dielectric layer. In use, a voltage can be applied to clamp 300, for example, several kV. And current can flow through the resistive layer, such that the voltage at an upper surface of the resistive layer will substantially be the same as the voltage of the electrode and generate an electric field. Also, a Coulomb force, attractive force between electrically opposite charged particles, will attract an object to clamp 300 and hold the object in place. In some aspects, clamp 300 can be a rigid material, for example, a metal, a dielectric, a ceramic, or a combination thereof.

### Example Reticle Exchange Apparatus

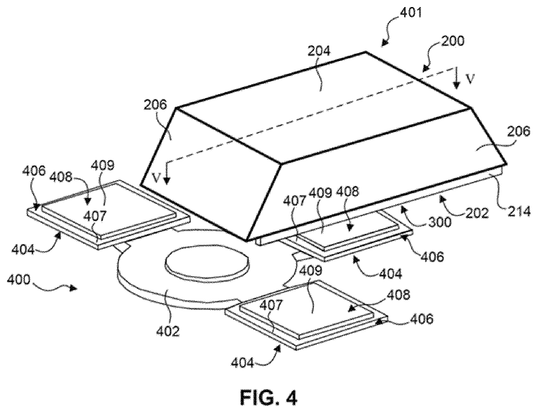

FIGS. 4, 5, 6A, 6B, and 6C show a reticle exchange apparatus 401, according to some aspects. Reticle exchange apparatus 401 can be configured to minimize reticle exchange time, particle generation, and contact forces or stresses from clamp 300 and/or reticle 408 to reduce damage to clamp 300 and reticle 408 and increase overall throughput in a reticle exchange process, for example, in a lithographic apparatus 100 and/or lithographic apparatus 100′.

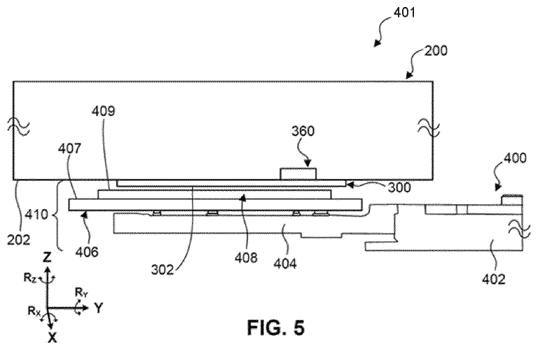

As shown in FIGS. 4 and 5, reticle exchange apparatus 401 can include reticle stage 200, clamp 300, and in-vacuum robot 400. In-vacuum robot 400 can include reticle handler 402.

In some aspects, reticle handler 402 can be a rapid exchange device (RED), which is configured to efficiently rotate and minimize reticle exchange time. For example, reticle handler 402 can save time by moving multiple reticles from one position to another substantially simultaneously, instead of serially.

In some aspects, as shown in FIG. 4, reticle handler 402 can include one or more reticle handler arms 404. Reticle handler arm 404 can include reticle baseplate 406. Reticle baseplate 406 can be configured to hold an object, for example, reticle 408.

In some aspects, reticle baseplate 406 can be an extreme ultraviolet inner pod (EIP) for a reticle. In some aspect, reticle baseplate 406 includes reticle baseplate frontside 407, and reticle 408 includes reticle backside 409.

In some aspects, as shown in FIGS. 4 and 5, reticle baseplate 406 can hold reticle 408 such that reticle baseplate frontside 407 and reticle backside 409 each face top stage surface 202 and clamp frontside 302. For example, reticle baseplate frontside 407 and reticle backside 409 can be facing perpendicularly away from top stage surface 202 and clamp frontside 302.

As shown in FIG. 5, reticle exchange apparatus 401 can include reticle exchange area 410, which is the cross-sectional area between clamp 300, reticle 408, reticle baseplate 406, and reticle handler arm 404 during a reticle exchange process.

In some aspects, as shown in FIG. 4, reticle handler arms 404 can be arranged symmetrically about reticle handler 402. For example, reticle handler arms 404 can be spaced from each other by about 90 degrees, 120 degrees, or 180 degrees. In some aspects, reticle handler arms 404 can be arranged asymmetrically about reticle handler 402. For example, two reticle handler arms 404 can be spaced from each other by about 135 degrees, while another two reticle handler arms 404 can be spaced from each other by about 90 degrees.

In one example, during a reticle exchange process, reticle handler arm 404 of reticle handler 402 positions reticle 408 on reticle baseplate 406 towards clamp 300 in reticle exchange area 410. As described above, a reticle handoff from reticle handler 402 to clamp 300 includes an unknown reticle position offset, which includes a reticle vertical distance offset (i.e., Z-direction offset) and a reticle tilt offset (i.e., R_{X} offset and R_{Y} offset). Tilt or excessive non-alignment between clamp 300 and reticle 408 can be a source of particle generation and can damage reticle 408 or clamp 300 over time. Reticle backside 409 and clamp frontside 302 can be in coplanar alignment for a final handoff. Despite calibration, variations still exist due to reticle mechanical and positioning tolerances, which can lead to high corner impacts and unpredictable first contact points between clamp 300 and reticle 408.

In one example, the reticle exchange process can involve lowering reticle stage 200 with clamp 300, which starts far away from reticle handler 402, as close to reticle 408 as possible until clamp 300 contacts reticle 408 to account for all possible offsets and/or tilts. During a reticle exchange process, reticle stage 200 with clamp 300 can be adjusted in a multi-stage movement.

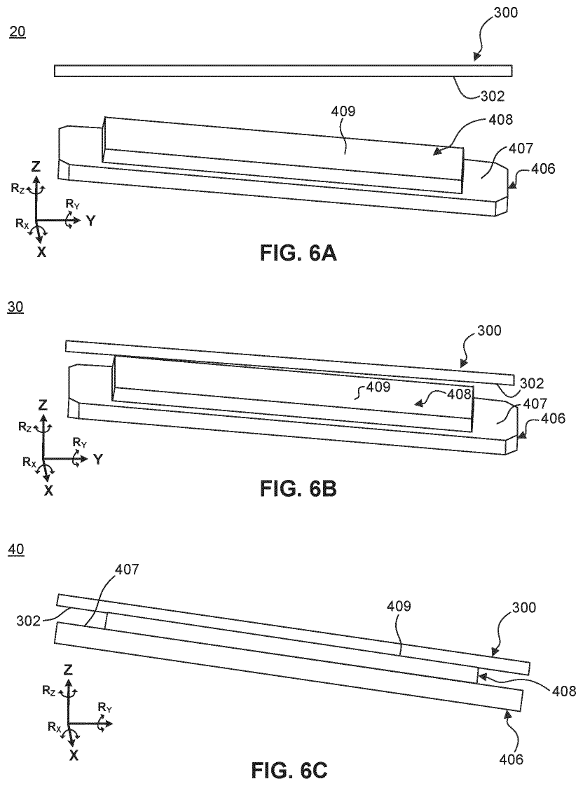

As shown in FIGS. 6A through 6C, reticle exchange apparatus 401 can include clamp 300, reticle 408, and reticle baseplate 406. The multi-stage movement can occur in four stages: (1) approach; (2) first contact; (3) full contact; and (4) voltage applied to clamp.

First, as shown in FIG. 6A, reticle exchange apparatus 401 can be in an approach configuration 20 and clamp 300 can be adjusted in a substantially vertical direction (i.e., Z-direction) toward reticle backside 409. In approach configuration 20, clamp 300 is turned off (i.e., no applied voltage) and reticle handler 402 deactivates the vertical direction (i.e., Z-direction) and tilt (i.e., R_{X} and R_{Y}, rotation about X-direction and rotation about Y-direction, respectively) servo motors of reticle handler arm 404 in reticle exchange area 410. The motors (i.e., Z, R_{X}, and R_{Y}) brake and rotation about Z-direction (i.e., R_{Z}) activates.

Second, as shown in FIG. 6B, reticle exchange apparatus 401 can be in a first contact configuration 30 and clamp 300 can be adjusted in a substantially vertical direction (i.e., Z-direction) toward reticle backside 409 until clamp 300 makes contact with reticle backside 409. In first contact configuration 30, clamp 300 is turned off and clamp 300 makes contact with reticle backside 409, for example, a corner of reticle 408, and then rotates or tilts about the contact (i.e., R_{X} and R_{Y}).

Third, as shown in FIG. 6C, reticle exchange apparatus 401 can be in a full contact configuration 40 and clamp 300 can be rotationally adjusted about the contact (i.e., R_{X} and R_{Y}) toward reticle backside 409 until clamp 300 makes full contact with reticle backside 409. In full contact configuration 40, clamp 300 is turned off and clamp 300 makes full contact with reticle backside 409, for example, all four corners of reticle 408, and is coplanar with reticle backside 409.

In some aspects, in full contact configuration 40, clamp 300 makes contact with all four corners of reticle 408 and continues to move in a substantially vertical direction (i.e., Z-direction) until a mechanical force of at least 5 N is achieved.

Fourth, with clamp frontside 302 and reticle backside 409 aligned and coplanar, clamp 300 is turned on (i.e., a voltage is applied to clamp 300) and reticle 408 is held in a fixed plane on clamp 300.

In some aspects, as shown in FIG. 5, reticle exchange apparatus 401 can include clamp controller 360. Clamp controller 360 can be coupled to clamp 300 and be configured to control a position of clamp 300. For example, clamp controller 360 can be configured to control reticle stage 200 to allow compliant movement of clamp 300. In some aspects, clamp controller 360 can be coupled to servo motors or servo actuators (i.e., X-direction, Y-direction, Z-direction, R_{X}, R_{Y}, R_{Z}) of reticle stage 200 and/or clamp 300. For example, clamp controller 360 can control translations of reticle stage 200 with clamp 300 along an x-axis, y-axis, and z-axis (i.e., X-direction, Y-direction, Z-direction) and rotations about the x-axis, y-axis, and z-axis (i.e., R_{X}, R_{Y}, R_{Z}), where the x-axis, y-axis, and z-axis are orthogonal coordinates.

### Example Chuck

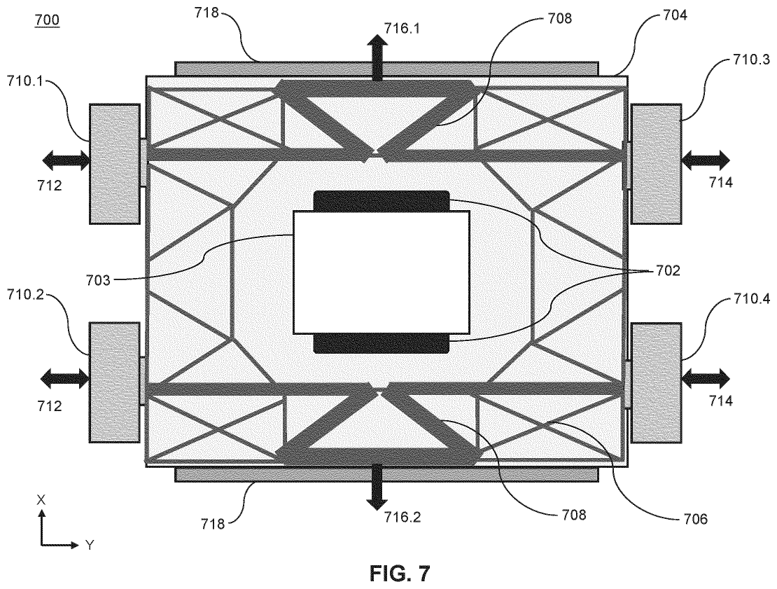

FIG. 7 shows a cross-section of a reticle stage 700 in a horizontal XY-plane, according to some aspects. In some aspects, reticle stage 700 can comprise clamps 702, a chuck 704, a patterned internal structure 706 including an auxetic structure 708, actuators 710, and encoder scales 718, e.g., of an encoder similar to as discussed above. In some aspects, reticle stage 700 can be implemented in lithographic apparatus 100 and/or lithographic apparatus 100′. For example, reticle stage 700 can be support structure MT in lithographic apparatus 100 and/or lithographic apparatus 100′.

In some aspects, reticle stage 700 can include clamps 702 disposed around a cavity 703 of a chuck 704 to receive reticles for scanning or patterning. Clamps 702 can be configured to hold a reticle (not shown) in a fixed plane on reticle stage 700. In some aspects, clamps 702 can use mechanical, vacuum, electrostatic, or other suitable clamping techniques to hold and secure an object. In some aspects, each clamp 702 can be an electrostatic clamp, which can be configured to electrostatically clamp (i.e., hold) an object, for example, a reticle in a vacuum environment. For EUV generation performed in a vacuum environment, it can be difficult to use vacuum clamps to clamp a mask or reticle. Instead, electrostatic clamp(s) can be used. For example, each clamp 702 can include an electrode, a resistive layer on the electrode, a dielectric layer on the resistive layer, and burls projecting from the dielectric layer. In use, a voltage can be applied to each clamp 702, for example, several kV. And current can flow through the resistive layer, such that the voltage at an upper surface of the resistive layer will substantially be the same as the voltage of the electrode and generate an electric field. Also, a Coulomb force, attractive force between electrically opposite charged particles, can attract an object to each clamp 702 and hold the object in place. In some aspects, each clamp 702 can be a rigid material, for example, a metal, a dielectric, a ceramic, or a combination thereof.

In some aspects, reticle stage 700 can include the body of a chuck 704 to support clamps 702 for holding a reticle. Chuck 704 can include a cavity 703 to receive reticles for scanning or patterning. In some aspects, chuck 704 can be any shape with dimensions suitable for use in lithographic apparatus 100 and/or lithographic apparatus 100′. For example, as shown in FIG. 7, a XY-cross section of chuck 704 can have a rectangular shape with a length of 562 mm and width of 400 mm. In some aspects, chuck 704 can be made of various materials, such as ceramic or glass. For example, chuck 704 can be made of Zerodur® brand glass-ceramic.

In some aspects, reticle stage 700 can include encoder scales 718 for positioning operations. For example, encoder scales 718 can be interferometers. As shown in FIG. 7, encoder scales 718 can be attached along a longitudinal Y-direction of reticle stage 700. In some aspects, encoder scales 718 can be attached along a lateral X-direction of reticle stage 700. In some aspects, one encoder scales 718 can be parallel or orthogonal to a second encoder scale 718.

In some lithographic apparatuses, for example, lithographic apparatus 100 and/or lithographic apparatus 100′, a reticle stage 700 with a clamp 702 can be used to hold and position a reticle for scanning or patterning operations. In one example, the reticle stage 700 can rely on powerful drives, large balance masses, and heavy frames to support it. In one example, the reticle stage 700 can have a large inertia and can weigh over 500 kg to propel and position a reticle weighing about 0.5 kg. To accomplish reciprocating motions of the reticle, which are typically found in lithographic scanning or patterning operations, actuators 710 (e.g., 710.1 to 710.n, wherein n is an integer value of 1 or more) can drive the reticle stage 700 by pushing or pulling on chuck 704 with accelerating and decelerating forces. In some aspects, as seen in FIG. 7, first to fourth actuators 710.1 to 710.4 can be mounted on the body of chuck 704. First and second actuators 710.1 and 710.2 can push or pull on chuck 704 in a first direction 712. Third and fourth actuators 710.3 and 710.4 can push or pull on chuck 704 in a second direction 714 opposite the first direction 712.

In some aspects, when a chuck is pushed or pulled by actuators, the shape of the chuck can deform by multiple microns or nanometers, e.g., the chuck can contract in an X-direction when stretched in a Y-direction. In some aspects, the contraction of a chuck in an X-direction can be amplified in the central region where a cavity receives a reticle. Additionally, pushing or pulling by actuators can deform various interfaces on a chuck, such as clamps and encoder scales. These interfaces can require nanometer accuracy, so deformations should be minimized.

In some aspects, deformations that result from pushing or pulling by actuators can be explained by Poisson's ratio, which is the ratio of lateral deformation to longitudinal deformation. Poisson's ratio applies to homogeneous materials, cellular porous structures, and geometrically pre-defined/programmed cellular structures. A material with a positive Poisson's ratio expands in one direction and contracts in a transverse direction. A material with a negative Poisson's ratio, called an auxetic material, expands in one direction and expands in a transverse direction. Geometrically tailored materials, like cellular mechanisms, can exhibit auxetic behavior.

In some aspects, reticle stage 700 can counteract deformations from the pushing or pulling by actuators 710 through including a patterned internal structure 706 within the body of chuck 704 to make chuck 704 stiffer. A portion of patterned internal structure 706 can be an auxetic structure 708 to spatially tailor the Poisson's ratio of chuck 704 according to regions that need to resist deformation. In response to actuators 710 pushing or pulling on chuck 704 in first direction 712 and second direction 714, auxetic structure 708 opens up and expands in a transverse direction 716 (e.g., 716.1 to 716.n, wherein n is an integer value of 1 or more), thereby compensating for the contraction of chuck 704 in the X-direction. This auxetic structure 708 can achieve a net-zero X-deformation of the chuck 704.

In some aspects, patterned internal structure 706 and auxetic structure 708 can have various shapes, thicknesses, and spatial locations to tailor local deformations. Patterned internal structure 706 can form shapes that have a positive, zero, or negative Poisson's ratio. Auxetic structure 708 can form shapes that have a negative Poisson's ratio, such as hollow triangular regions, hollow hourglass regions, etc. Patterned internal structure 706 can vary in thickness depending on the region of chuck 704. Auxetic structure 708 can be thicker or thinner than other portions of the patterned internal structure 706. Patterned internal structure 706 can include auxetic structure 708 at predetermined locations desired for expansion to resist local deformations.

In some aspects, patterned internal structure 706 and auxetic structure 708 can be formed within the body of chuck 704. For example, a material for chuck 704 can be machined to remove material partially throughout the body of chuck 704 to form patterned internal structure 706 and auxetic structure 708. With this configuration, patterned internal structure 706 and auxetic structure 708 can be part of a monolithic body of chuck 704.

In some aspects, patterned internal structure 706 and auxetic structure 708 can be coupled to chuck 704. Patterned internal structure 706 and auxetic structure 708 can be separately manufactured parts made of the same material as chuck 704 and coupled to chuck 704 by way of glue, bolts, etc.

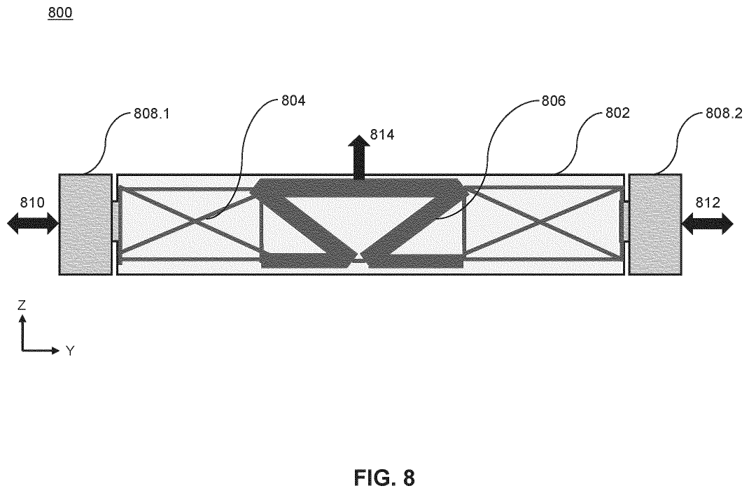

FIG. 8 shows a cross-section of a reticle stage 800 in a vertical YZ-plane, according to some aspects. In some aspects, reticle stage 800 comprises a chuck 802, an internal structure 804 including an auxetic structure 806, and actuators 808. In some aspects, reticle stage 800 can be implemented in lithographic apparatus 100 and/or lithographic apparatus 100′. For example, reticle stage 800 can be support structure MT in lithographic apparatus 100 and/or lithographic apparatus 100′. The above discussion of reticle stage 700 from FIG. 7 can apply to reticle stage 800.

In some aspects, reticle stage 800 can include the body of a chuck 802 to support clamps holding a reticle. In some aspects, chuck 802 can be any shape with dimensions suitable for use in lithographic apparatus 100 and/or lithographic apparatus 100′. For example, as shown in FIG. 8, a YZ-cross section of chuck 802 can have a rectangular shape with a length of 562 mm and height of 62 mm. In some aspects, chuck 802 can be made of various materials, such as ceramic or glass. For example, chuck 802 can be made of Zerodur® brand glass-ceramic.

In some aspects, reticle stage 800 can include actuators 808 (e.g., 808.1 to 808.n, wherein n is an integer value of 1 or more) to drive reticle stage 800 by pushing or pulling on chuck 802 with accelerating and decelerating forces. In some aspects, as seen in FIG. 8, first and second actuators 808.1 to 808.2 can be mounted on the body of chuck 802. First actuator 808.1 can push or pull on chuck 802 in a first direction 810. Second actuator 808.2 can push or pull on chuck 802 in a second direction 812 opposite the first direction 810. When chuck 802 is pushed or pulled by actuators 808, the shape of chuck 802 can deform by multiple microns or nanometers.

In some aspects, reticle stage 800 can counteract such deformations from the pushing or pulling by actuators 808 through including a patterned internal structure 804 within the body of chuck 802 to make chuck 802 stiffer. A portion of patterned internal structure 804 can be an auxetic structure 806 to spatially tailor the Poisson's ratio of chuck 802 according to regions that need to resist deformation. In some aspects, auxetic structure 806 can be disposed in at least one of a vertical YZ-plane or XZ-plane. In response to actuators 808 pushing or pulling on chuck 802 in first direction 810 and second direction 812, auxetic structure 806 opens up and expands in a transverse direction 814 to resist torsion, thereby compensating for the contraction of chuck 802 in the Z-direction. This auxetic structure 806 can achieve a net-zero Z-deformation of the chuck 802 to yield a higher torsional mode.

In some aspects, patterned internal structure 804 and auxetic structure 806 can have various shapes, thicknesses, and spatial locations to tailor local deformations. Patterned internal structure 804 can form shapes that have a positive, zero, or negative Poisson's ratio. Auxetic structure 806 can form shapes that have a negative Poisson's ratio, such as hollow triangular regions, hollow hourglass regions, etc. Patterned internal structure 804 can vary in thickness depending on the region of chuck 802. Auxetic structure 806 can be thicker or thinner than other portions of the patterned internal structure 804. Patterned internal structure 804 can include auxetic structure 806 at predetermined locations desired for expansion to resist local deformations.

In some aspects, patterned internal structure 804 and auxetic structure 806 can be formed within the body of chuck 802. For example, a material for chuck 802 can be machined to remove material partially throughout the body of chuck 802 to form patterned internal structure 804 and auxetic structure 806. With this configuration, patterned internal structure 804 and auxetic structure 806 can be part of a monolithic body of chuck 802.

In some aspects, patterned internal structure 804 and auxetic structure 806 can be coupled to chuck 802. Patterned internal structure 804 and auxetic structure 806 can be separately manufactured parts made of the same material as chuck 802 and coupled to chuck 802 by way of glue, bolts, etc. to create a locked geometry structure for high stiffness.

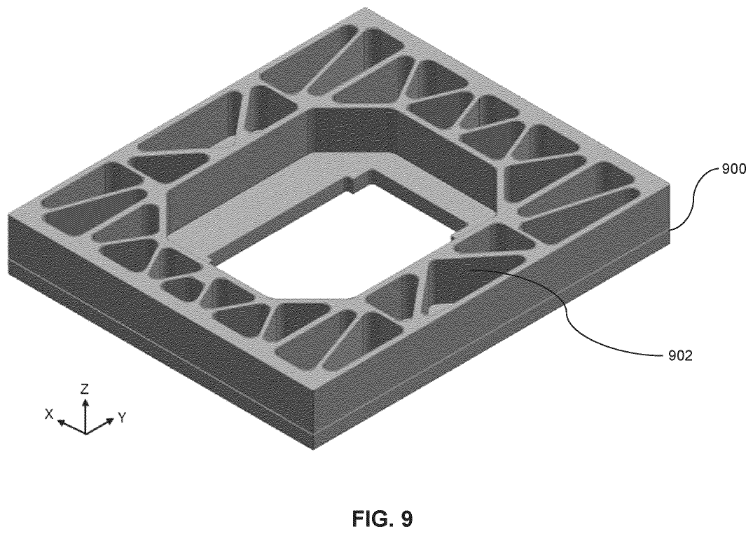

FIG. 9 shows a perspective view of a chuck 900, according to some aspects. In some aspects, chuck 900 can be implemented in lithographic apparatus 100 and/or lithographic apparatus 100′. For example, chuck 900 can be part of support structure MT in lithographic apparatus 100 and/or lithographic apparatus 100′. The above discussion of chuck 704 from FIG. 7 and chuck 802 from FIG. 8 can apply to chuck 900.

In some aspects, chuck 900 can be any shape with dimensions suitable for use in lithographic apparatus 100 and/or lithographic apparatus 100′. For example, chuck 900 can have a rectangular shape with a length of 562 mm, width of 400 mm, and height of 62 mm. In some aspects, chuck 900 can be made of various materials, such as ceramic or glass. For example, chuck 900 can be made of Zerodur® brand glass-ceramic.

In some aspects, chuck 900 can include an auxetic structure 902. Auxetic structure 902 can have various shapes, thicknesses, and spatial locations to tailor local deformations. Auxetic structure 902 can form shapes that have a negative Poisson's ratio, such as hollow triangular regions, hollow hourglass regions, etc. Auxetic structure 902 can be thicker or thinner than other portions of a patterned internal structure within chuck 900. Auxetic structure 902 can be disposed at predetermined locations desired for expansion to resist local deformations.

In some aspects, auxetic structure 902 can be formed within the body of chuck 900. For example, a material for chuck 900 can be machined to remove material partially throughout the body of chuck 900 to form a patterned internal structure that contains auxetic structure 902. With this configuration, auxetic structure 902 can be part of a monolithic body of chuck 900.

In some aspects, auxetic structure 902 can be coupled to chuck 900. Auxetic structure 902 can be separately manufactured parts made of the same material as chuck 900 and coupled to chuck 900 by way of glue, bolts, etc.

The terms “radiation,” “beam,” “light,” “illumination,” or the like can be used herein to refer to one or more types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

Various embodiments of the present system and methods are disclosed in the subsequent list of numbered clauses. In the following, further features, characteristics, and exemplary technical solutions of the present disclosure will be described in terms of clauses that may be optionally claimed in any combination:
1. A lithographic apparatus, comprising:
   an illumination system configured to produce a beam of radiation;
   a patterning system configured to impart a pattern on the beam, the patterning system comprising a reticle;
   a projection system configured to project the patterned beam on a substrate; and
   a reticle stage comprising:
      a reticle clamp configured to support the reticle; and
      a chuck configured to support the reticle clamp wherein:
         the chuck includes a patterned internal structure;
         a portion of the patterned internal structure is an auxetic structure; and
         the auxetic structure is thicker or thinner than other portions of the patterned internal structure.
2. The lithographic apparatus of clause 1, further comprising first, second, third, and fourth actuators configured to push or pull on the chuck.
3. The lithographic apparatus of clause 2, wherein:
   the first and second actuators push or pull on the chuck in a first direction, and
   the third and fourth actuators push or pull on the chuck in a second direction opposite the first direction.
4. The lithographic apparatus of clause 3, wherein in response to the first and second or third and fourth actuators pushing or pulling, the auxetic structure expands in a transverse direction to the first and second directions.
5. The lithographic apparatus of clause 1, wherein the auxetic structure is disposed in a horizontal XY-plane.
6. The lithographic apparatus of clause 1, wherein the auxetic structure is disposed in at least one of a vertical YZ-plane or XZ-plane.
7. The lithographic apparatus of clause 1, wherein a shape of the auxetic structure forms hollow triangular regions.
8. The lithographic apparatus of clause 1, wherein the auxetic structure is formed within the chuck body.
9. The lithographic apparatus of clause 1, wherein the auxetic structure is coupled to the chuck.
10. A system comprising:
   a reticle clamp configured to support a reticle; and
   a chuck configured to support the reticle clamp wherein:
      the chuck includes a patterned internal structure;
      a portion of the patterned internal structure is an auxetic structure; and
      the auxetic structure is thicker or thinner than other portions of the patterned internal structure.
11. The system of clause 10, wherein the system is disposed on a reticle stage.
12. The system of clause 10, further comprising first, second, third, and fourth actuators configured to push or pull on the chuck.
13. The system of clause 12, wherein:
   the first and second actuators push or pull on the chuck in a first direction, and
   the third and fourth actuators push or pull on the chuck in a second direction opposite the first direction.
14. The system of clause 13, wherein in response to the first and second or third and fourth actuators pushing or pulling, the auxetic structure expands in a transverse direction to the first and second directions.
15. The system of clause 10, wherein the auxetic structure is disposed in a horizontal XY-plane.
16. The system of clause 10, wherein the auxetic structure is disposed in at least one of a vertical YZ-plane or XZ-plane.
17. The system of clause 10, wherein a shape of the auxetic structure forms hollow triangular regions.
18. The system of clause 10, wherein the auxetic structure is formed within the chuck body.
19. The system of clause 10, wherein the auxetic structure is coupled to the chuck.
20. A method comprising:
   pushing or pulling a chuck in a first direction during a first time period with first and second actuators;
   pushing or pulling the chuck in a second direction, opposite the first direction, during a second time period with third and fourth actuators; and
   counteracting deformation of the chuck from the pushing or pulling with an auxetic structure within or coupled to the chuck, the auxetic structure being configured to expand in a transverse direction to the first and second directions.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1. A lithographic apparatus, comprising:
an illumination system configured to produce a beam of radiation;
a patterning system configured to impart a pattern on the beam, the patterning system comprising a reticle;
a projection system configured to project the patterned beam on a substrate; and
a reticle stage comprising:
a reticle clamp configured to support the reticle; and
a chuck configured to support the reticle clamp wherein:
the chuck includes a patterned internal structure;
a portion of the patterned internal structure is an auxetic structure; and
the auxetic structure is thicker or thinner than other portions of the patterned internal structure.

2. The lithographic apparatus of claim 1, further comprising first, second, third, and fourth actuators configured to push or pull on the chuck, wherein:
the first and second actuators push or pull on the chuck in a first direction;
the third and fourth actuators push or pull on the chuck in a second direction opposite the first direction; and
in response to the first and second or third and fourth actuators pushing or pulling, the auxetic structure expands in a transverse direction to the first and second directions.

3. The lithographic apparatus of claim 1, wherein the auxetic structure is disposed in a horizontal XY-plane.

4. The lithographic apparatus of claim 1, wherein the auxetic structure is disposed in at least one of a vertical YZ-plane or XZ-plane.

5. The lithographic apparatus of claim 1, wherein a shape of the auxetic structure forms hollow triangular regions.

6. The lithographic apparatus of claim 1, wherein the auxetic structure is formed within the chuck body.

7. The lithographic apparatus of claim 1, wherein the auxetic structure is coupled to the chuck.

8. A system comprising:
a reticle clamp configured to support a reticle; and
a chuck configured to support the reticle clamp wherein:
the chuck includes a patterned internal structure;
a portion of the patterned internal structure is an auxetic structure; and
the auxetic structure is thicker or thinner than other portions of the patterned internal structure.

9. The system of claim 8, wherein the system is disposed on a reticle stage.

10. The system of claim 8, further comprising first, second, third, and fourth actuators configured to push or pull on the chuck, wherein:
the first and second actuators push or pull on the chuck in a first direction;
the third and fourth actuators push or pull on the chuck in a second direction opposite the first direction; and
in response to the first and second or third and fourth actuators pushing or pulling, the auxetic structure expands in a transverse direction to the first and second directions.

11. The system of claim 8, wherein the auxetic structure is disposed in a horizontal XY-plane or is disposed in at least one of a vertical YZ-plane or XZ-plane.

12. The system of claim 8, wherein a shape of the auxetic structure forms hollow triangular regions.

13. The system of claim 8, wherein the auxetic structure is formed within the chuck body.

14. The system of claim 8, wherein the auxetic structure is coupled to the chuck.

15. A method comprising:
pushing or pulling a chuck in a first direction during a first time period with first and second actuators;
pushing or pulling the chuck in a second direction, opposite the first direction, during a second time period with third and fourth actuators; and
counteracting deformation of the chuck from the pushing or pulling with an auxetic structure within or coupled to the chuck, the auxetic structure being configured to expand in a transverse direction to the first and second directions.
